(19) United States
(12) Patent Application Publication
(10) Pub. No.: US 2021/0028305 A1
(43) Pub. Date: Jan. 28, 2021

(54) TRENCH MOSFETS WITH OXIDE CHARGE BALANCE REGION IN ACTIVE AREA AND JUNCTION CHARGE BALANCE REGION IN TERMINATION AREA

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/517,743

(22) Filed: Jul. 22, 2019

(51) Int. Cl. H01L 29/78; H01L 29/872; H01L 29/66

(52) U.S. Cl. CPC H01L 29/7813; H01L 29/66734; H01L 29/872

(57) ABSTRACT

A trench MOSFET with oxide charge balance region in active area and junction balance region in termination area is disclosed. The inventive structure can reduce specific on-resistance and enhance avalanche capability. The device structure is achieved using angle implant of N and P columns.

### FIELD OF THE INVENTION

This invention relates generally to the cell structure, device configuration and fabrication process of power semiconductor devices. More particularly, this invention relates to a novel and improved cell structure, device configuration and improved fabrication process of a shielded gate MOSFET (Metal Oxide Semiconductor Field Effect Transistor).

### BACKGROUND OF THE INVENTION

Please refer to FIG. 1A and FIG. 1B for shielded gate trench MOSFETs disclosed in the prior art of U.S. Pat. Nos. 8,373,224 and 8,373,225 respectively, wherein junction charge balance regions having super-junction structure with N and P type columns are in active and termination areas. Both arts have good avalanche capability and are less sensitive to the oxide thickness variation of the thick oxide surrounding the source electrode. However, they suffer from high Rsp (specific on-resistance) issue due to the large mesa pitch required for formation of the super-junction structure in active area.

Please refer to FIG. 1C for a trench MOSFET with split gates and diffused drift region in the prior art of U.S. Pat. No. 8,587,054, in which oxide charge balance regions having only N type column are in active and termination areas. Prior art illustrated in FIG. 1C is good to have smaller mesa pitch for lower Rsp. Nevertheless, it is very sensitive to oxide thickness variation of thick oxide surrounding source electrode causing low BV (Breakdown Voltage) and poor avalanche capability in termination area near edge of active area.

Therefore, there is still a need in the art of the semiconductor power device, particularly for shielded gate trench MOSFET design and fabrication, to provide a novel cell structure, device configuration that would resolve these difficulties and design limitations to achieve lower Rsp and better avalanche capability simultaneously.

### SUMMARY OF THE INVENTION

The present invention provides a shielded gate trench MOSFET with oxide charge balance region in active area and junction charge balance region in termination area by simply reducing mesa width in active area less than twice of N column diffusion width (W_{MS}<2 W_{N}). Therefore, Lower Rsp due to smaller mesa width and better avalanche capability as result of junction charge balance region existing in termination area would be achieved simultaneously. The mesa area only has net N doped charge because the N type Column (NC) overrides P type Column (PC) after NC/PC diffusion. It is well known that avalanche capability is better when breakdown voltage in active area is lower than that of termination region so that avalanche current flows through source metal instead of termination area. The invented structures with the junction charge balance region in the termination area ensure more consistent breakdown voltage in the termination area than active area.

In one aspect, the present invention features a shielded gate trench MOSFET comprising: a substrate of a first conductivity type; an epitaxial layer of the first conductivity type onto the substrate, wherein the epitaxial layer has a lower doping concentration than the substrate; a plurality of gate trenches starting from a top surface of the epitaxial layer and extending downward into the epitaxial layer in an active area; a first gate insulation layer formed along trench sidewalls of a lower portion of each of the gate trenches; a source electrode formed within each of the gate trenches and surrounded by the first gate insulation layer in the lower portion of each of the gate trenches; a second gate insulation layer formed at least along trench sidewalls of an upper portion of each of the gate trenches and upper sidewalls of the source electrode above the first gate insulation layer, wherein the second gate insulation layer has a thinner thickness than the first gate insulation layer; a pair of split gate electrodes disposed adjacent to the second gate insulation layer and above the first gate insulation layer in the upper portion of each of the gate trenches, wherein the gate electrode and the shielded electrode are doped poly-silicon layers; an oxide charge balance region of the first conductivity and having a higher doping concentration than the epitaxial layer, disposed in a mesa between two adjacent the gate trenches; the oxide charge balance region has a higher doping concentration near trench sidewalls of the gate trenches than in the center of the mesa; a body region of a second conductivity type formed in the mesa, above a top surface of the oxide charge region, and a source region of the first conductivity type formed near a top surface of the body region and adjacent to the split gate electrodes, and a junction balance region is formed near edge of the active area in a termination area consisting of a first doped column region of the first conductivity type having a higher doping concentration than the epitaxial layer, and a second doped column region of the second conductivity type adjacent to the first doped column region.

In another aspect, the present invention features a shielded gate trench MOSFET comprising: a substrate of a first conductivity type; an epitaxial layer of the first conductivity type onto the substrate, wherein the epitaxial layer has a lower doping concentration than the substrate; a plurality of gate trenches formed starting from a top surface of the epitaxial layer and extending downward into the epitaxial layer in an active area; a first insulation layer along an inner surface of a lower portion of each of the trenches; a source electrode formed within the lower portion of each of the trenches and surrounded by the first insulation layer; a second insulation layer formed along inner surfaces of upper portion of each of the trenches and a top surface of the source electrode, wherein the second insulation layer has a thinner thickness than the first insulation layer; a gate electrode formed within the upper portion of each of the trenches and surrounded by the second insulation layer, wherein the gate electrode and the source electrode insulated from each other by a third insulation layer; the source electrode and the gate electrodes comprise a doped poly-silicon of the first conductivity type; an oxide charge balance region of the first conductivity disposed in a mesa between two adjacent gate trenches, which has a higher doping concentration than the epitaxial layer; the oxide charge balance region has a higher doping concentration near trench sidewalls of the gate trenches than in the center of the mesa; a body region of a second conductivity type formed in the mesa, which is above a top surface of the oxide charge region, and a source region of the first conductivity type formed near a top surface of the body region and adjacent to the split gate electrodes, and a junction balance region is formed in a termination area consist of a first doped column region of the first conductivity type having a higher doping concentration than the epitaxial layer, and a second doped column region of the second conductivity type adjacent to the first doped column region.

Preferred embodiments include one or more of the following features: the split gate electrodes disposed in the middle between the second insulation layer along upper portion of the source electrode and the second insulation layer adjacent trench sidewall of the gate trenches; the upper portion of the source electrode above the first insulation layer is fully oxidized during the second insulation layer growth when the source electrode is narrow enough; trench bottoms of the gate trenches are above a common interface between the substrate and the epitaxial layer; gate trenches further touch or extend into the substrate; the trench MOSFET further comprises a trenched source-body contact filled with a contact metal plug and penetrating through the source region and extending into the body region, and a body contact doped region of the second conductivity type within the body region and surrounding at least bottom of the trenched source-body contact underneath the source region, wherein the body contact doped region has a higher doping concentration than the body region, and the contact metal plug is a tungsten metal layer padded by a barrier metal layer of Ti/TiN or Co/TiN; the present invention further comprises a termination area which comprising a guard ring (GR) connected with the source region and the body region, wherein the GR of the second conductivity type have junction depths greater than the body region; the present invention further comprises a termination area which comprises multiple floating body regions having floating voltage in a termination area wherein the multiple floating body regions having same conductivity type and junction depths as the body regions, formed simultaneously as the body regions; the trench MOSFET further comprises a plurality of trenched source-body formed in an active area, each filled with a contact metal plug, penetrating through the source regions and the body regions and extending into said epitaxial layer, and a body contact doped region of the second conductivity type formed along an upper portion of sidewalls of the trenched source-body contacts below the source regions, wherein the body contact doped region has a higher doping concentration than the body regions, and a Schottky diode doped region surrounding bottoms and a lower portion of sidewalls of the trenched source-body contacts below the body contact doped region, wherein the Schottky diode doped region has either the first or the second conductivity doping type, and the contact metal plug is a tungsten metal layer padded by a barrier metal layer of Ti/TiN or Co/TiN.

The invention also features a method for manufacturing a shielded gate trench MOSFET comprising the steps of: (a) growing an epitaxial layer of a first conductivity type upon a substrate of the first conductivity type, wherein the epitaxial layer has a lower doping concentration than the substrate; (b) forming a hard mask such as an oxide onto a top surface of the epitaxial layer for definition of a plurality of gate trenches; (c) applying a trench mask on the block layer; (d) forming a plurality of gate trenches, and mesas between two adjacent gate trenches in the epitaxial layer by etching through open regions in the block layer; (e) keeping the block layer substantially covering the mesas after formation of the trenches to block sequential angle ion implantation into top surfaces of the mesas; (f) growing a screen oxide along an inner surface of the trenches; (g) carrying out an angle Ion Implantation of a second conductivity type dopant into the mesas through trench sidewalls of the gate trenches to form a plurality of first doped column regions in the mesas and adjacent to sidewalls of the gate trenches; (h) carrying out an angle Ion Implantation of the first conductivity type dopant into the mesas through trench sidewalls of the gate trenches to form a plurality of second doped column regions adjacent to the sidewalls of the gate trenches and in parallel with the first doped column regions; (i) diffusing both the first conductivity type dopant and the second conductivity type dopant into the mesas simultaneously to form the second doped column region between two adjacent gate trenches in the active area, and the first doped and the second doped column regions in termination area; (j) forming a thick oxide layer as the first insulation layer along inner surfaces of the gate trenches by thermal oxide growth or oxide deposition; (k) depositing a doped poly-silicon layer filling the gate trenches and close to the thick oxide layer to serve as source electrodes; (1) etching back the source electrode and the thick oxide layer from an upper portion of the trenches; (m) growing a thin oxide layer as the second insulation layer covering top surface of the thick oxide layer, along upper inner surfaces of the gate trenches and along sidewalls of the source electrodes; (n) depositing another doped poly-silicon layer filling the upper portion of the gate trenches and close to the thin oxide layer to serve as gate electrodes; (o) etching back the gate electrodes by CMP (Chemical Mechanical Polishing) or plasma etch; (p) applying a body mask onto a top surface of the epitaxial layer, carrying out a body implantation of the second conductivity type dopant and a step of body diffusion to form a body region; (q) removing the body mask and applying a source mask onto top surface of the epitaxial layer; (r) carrying out Ion Implantation of the first conductivity type dopant and diffusion to form a source region; (s) removing the source mask and depositing a contact interlayer onto a top surface of the epitaxial layer; and (t) applying a contact mask and etching a contact trench penetrating the contact interlayer, the source region and extending into the body region or into the epitaxy layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a cross-sectional view of a super-junction trench MOSFET of a prior art.

FIG. 1B is a cross-sectional view of a super-junction trench MOSFET of another prior art.

FIG. 1C is a cross-sectional view of a trench MOSFET of another prior art.

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 2D is a cross-sectional view of another preferred embodiment according to the present invention.

FIG. 2E is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIGS. 6A-6H are a serial of side cross-sectional views for showing the processing steps for fabricating the super-junction trench MOSFET as shown in FIG. 2E.

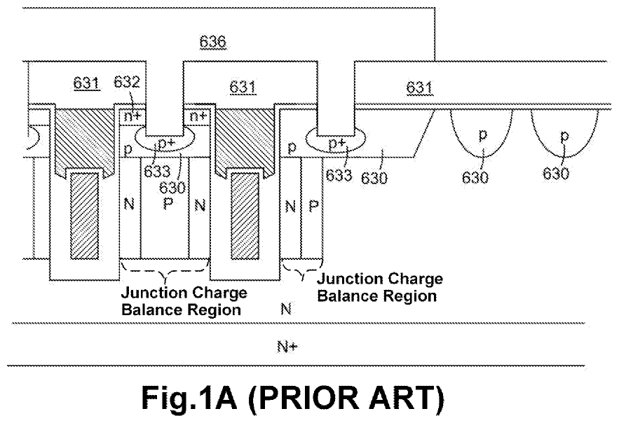

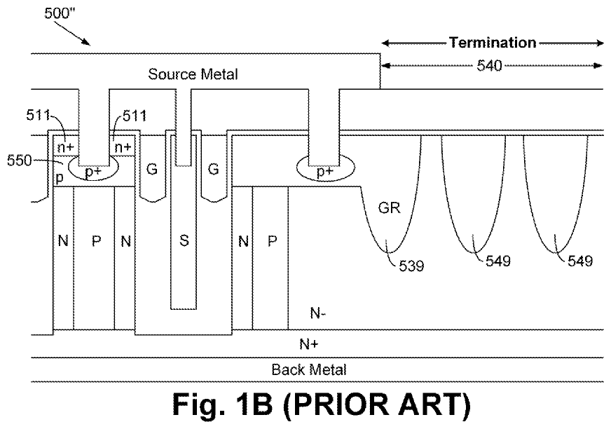

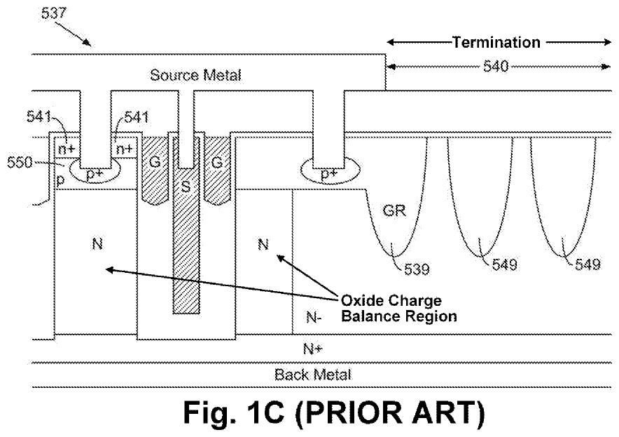

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

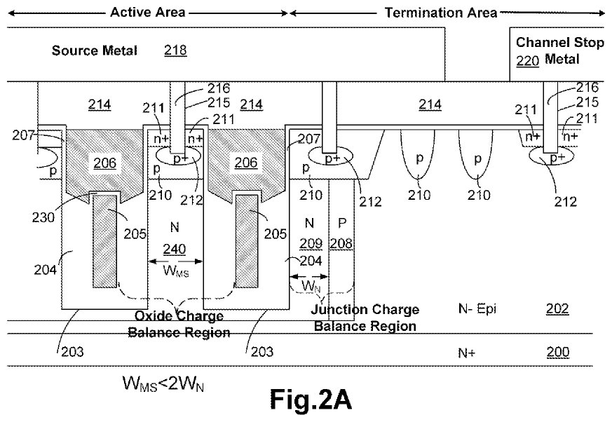

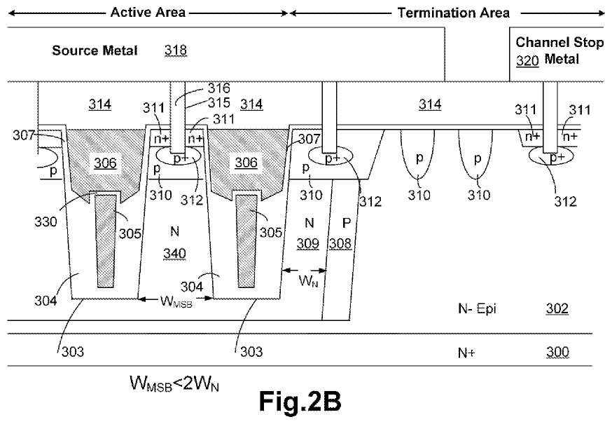

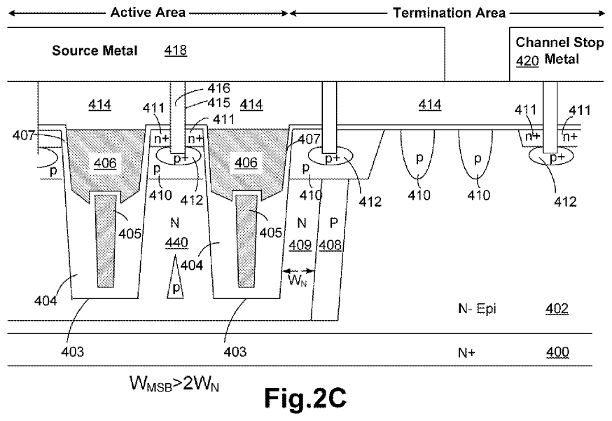

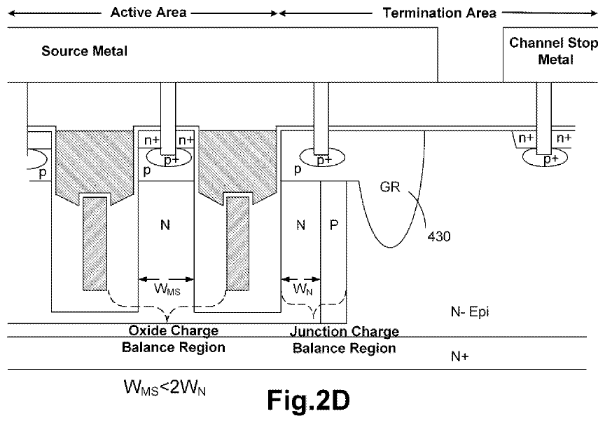

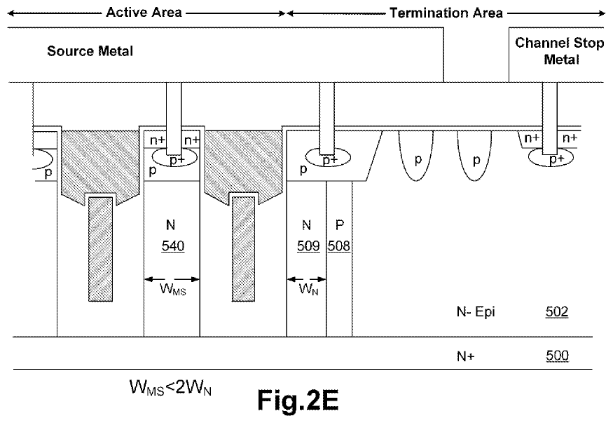

Please refer to FIG. 2A for a preferred embodiment of this invention where an N-channel shielded gate trench MOSFET having split gates with P body and multiple floating P bodies in a termination area is formed in an N− epitaxial layer 202 onto an N+ substrate 200. A plurality of gate trenches 203 are formed starting from a top surface of the N− epitaxial layer 202 and vertically down extending, not reaching the interface of the N− epitaxial layer 202 and the N+ substrate 200. Into each of the trenches 203, a doped poly-silicon layer is deposited filling a lower portion of the trench 203 to serve as a source electrode 205 padded by a first insulation layer 204. Into an upper portion of each of the gate trenches 203, another doped poly-silicon layer is deposited onto the first insulation layer 204 and surrounded by a second insulation layer 207 to serve as a gate electrode, wherein the second insulation layer 207 has a thinner thickness than the first insulation layer 204. The gate electrode 206 and the source electrode 205 are insulated from each other by a third insulation layer 230. Between the two adjacent trenches 203, an N type column region 209 is formed adjacent to sidewalls of the trenches. Onto a top surface of the N type doped column regions 209, a p body region 210 is formed with an n+ source region 211 near its top surface and flanking the trenches 203. Furthermore, in the p body region 210, a p+ body contact doped region 212 is formed surrounding at least bottom of the trenched source-body contact 215 underneath the n+ source region 211 to reduce the contact resistance between the p body region 210 and the contact metal plug 216 in the trenched source-body contact 215. The N-channel shielded gate trench MOSFET further comprises multiple floating P body regions 210 having floating voltage in a termination area. Besides, the source metal 218 is formed onto the contact interlayer 214 and connected with the contact metal plug 216, penetrating through the contact interlayer 214 to contact with the n+ source region 211, the p body region 210 and the p+ body contact doped region 212 in the active area, and only contact with the p body region 210 and the p+ body contact doped region 212 in the termination area. The channel stop metal 220 is formed onto the contact interlayer 214 and connected with contact metal plug 216 penetrating through the contact interlayer 214 to contact with the n+ source region 211, the epitaxy layer 202, and a p+ body contact doped region 212 in the termination area. In the present invention, oxide charge balance region including the first insulation 205 and the N doped mesa 240 in active area, and junction charge balance region including N column 209 and P column 208 in termination area are achieved by reducing mesa width W_{MS} less than twice of N column diffusion width W_{N} (W_{MS}<2 W_{N}). Therefore, Lower Rsp and better avalanche capability is achieved. The mesa 240 only has net N doped charge because the N type doped column (NC) overrides P type doped column (PC) after NC/PC diffusion.

FIG. 2B shows a cross-sectional view of another trench MOSFET according to the present invention. The trench MOSFET has a similar structure as the invention shown in FIG. 2A except that, in FIG. 2A, the gate trench in the active area is vertically downward, while that in FIG. 2B is tilt and the bottom of the mesa width is less than twice of the N column diffusion width (W_{MSB}<2 W_{N}).

FIG. 2C shows another preferred embodiment of the present invention, which is similar to the structure in FIG. 2B having tilt trench except that, in FIG. 2C there is a floating P island in the mesa area, when top of the mesa width is narrow than twice of N column diffusion width (W_{MSB}<2 W_{N}) but the bottom of the mesa width is bigger than twice of the N column diffusion width (W_{MSB}>2 W_{N}).

FIG. 2D shows another preferred embodiment of the present invention, which is similar to the structure in FIG. 2A except that, in FIG. 2D, the N-channel shielded gate trench MOSFET comprises a different termination area comprising a P type guard ring 430 (GR, as illustrated in FIG. 2D) having junction depth greater than the P body regions.

FIG. 2E shows another preferred embodiment of the present invention, which is similar to the structure in FIG. 2A except that, in FIG. 2E, the gate trenches are extending from the top surface of the epitaxial layer 502 and vertically down onto the interface of the N− epitaxy layer 502 and the N+ substrate 500. Besides, N type doped column 540 in active area, and N type doped column region 509 and P type doped column regions 508 in termination area are reaching the interface of the epitaxial layer 502 and the substrate 500.

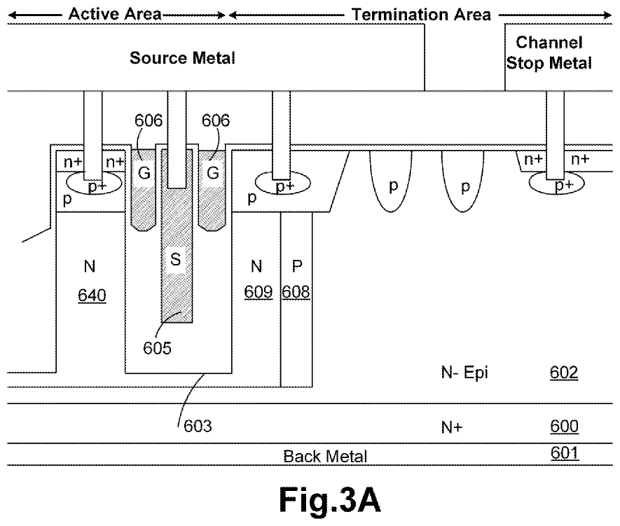

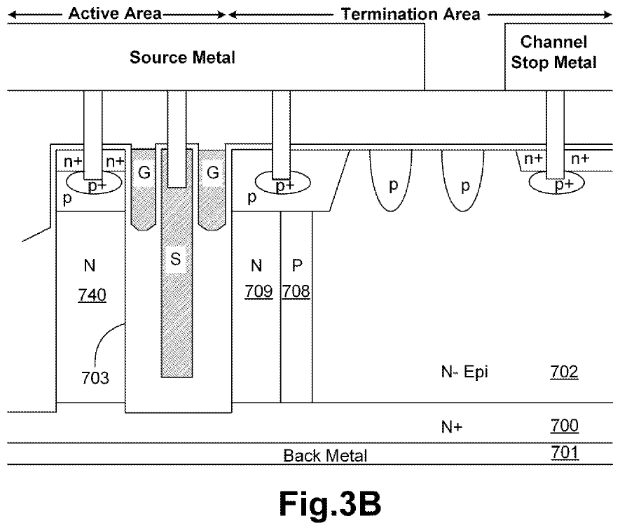

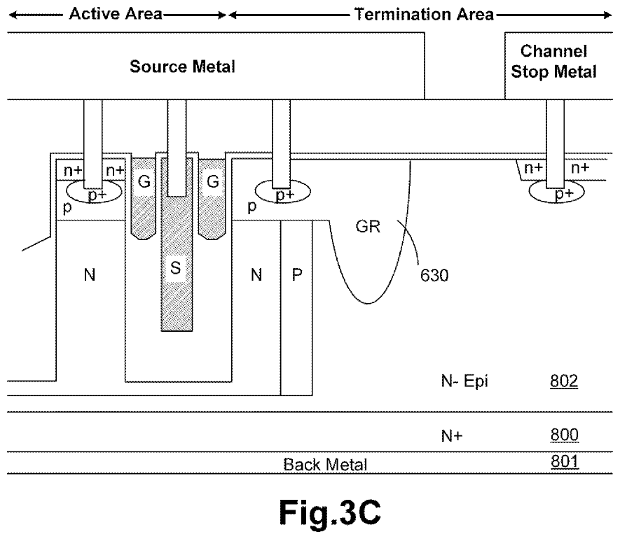

FIG. 3A shows another preferred embodiment of the present invention, which is similar to the structure in FIG. 2A except that a pair of split gate electrodes 606 are formed and each of the split electrode 606 is disposed in the middle between the source electrode 605 and adjacent to trench sidewall in each of the gate trenches 603. The source electrode 605 and the split gate electrodes 606 comprise a doped poly-silicon of N conductivity type. As an alternative, the source electrode 605 can be implemented comprising a doped poly-silicon of P conductivity type and the split gate electrodes 606 can be implemented comprising a doped poly-silicon of N conductivity type.

FIG. 3B shows another preferred embodiment of the present invention, which is similar to the structure in FIG. 3A except that, in FIG. 3B, the gate trenches 703 are extending from the top surface of the epitaxial layer and vertically down into the substrate 700. Besides, the N type doped column region 740 in the active area, and the N type doped column region 709 and P type doped column region 708 in the termination area are reaching the interface of the epitaxial layer 702 and the substrate 700.

FIG. 3C shows another preferred embodiment of the present invention, which is similar to the structure in FIG. 3A except that, in FIG. 3C, the N-channel shielded gate trench MOSFET comprises a different termination area comprising a P type guard ring 630 (GR, as illustrated in FIG. 3C) having junction depth greater than the P body regions.

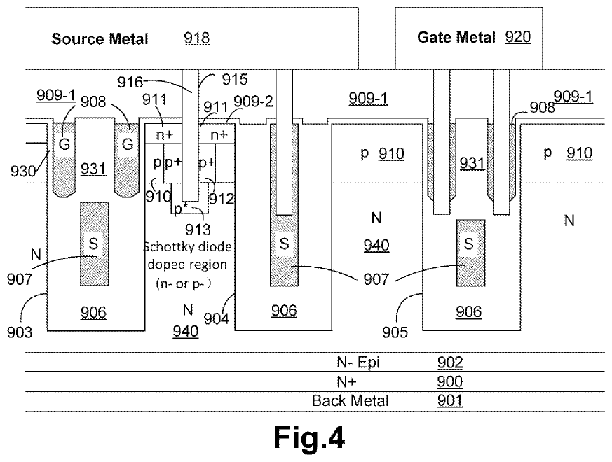

FIG. 4 shows another preferred embodiment of the present invention, wherein an N-channel trench MOSFET with an embedded Schottky diode is formed in an N type doped column 940 in active area. A plurality of gate trenches 903, 904 and 905 are formed starting from a top surface of the N− epitaxial layer 902 and extending downward into the N− epitaxial layer 902, not reaching the interface of the N− epitaxial layer 902 and the N+ substrate 900. Into each of the trenches 903 and 905, a doped poly-silicon layer is deposited filling a lower portion of the trench 903 and 905 to serve as a source electrode 907 padded by a first insulation layer 906. Into an upper portion of each of the trenches 903 and 905, another doped poly-silicon layer is deposited to serve as gate electrodes 908 onto the first insulation layer 906 and surrounded by second insulation layer 930. Top portion of the shielded gate between pair of the gate electrodes is narrow enough to be fully oxidized and converted into thermal oxide 931 during the second insulation layer 930 growth. Into each of the trenches 904, a doped poly-silicon layer is deposited from a top surface of the epitaxy layer 902 filling the trench 904 to serve as a source electrode 907. A plurality of P body regions 910 are formed in an upper portion of the N− epitaxial layer 902 and extending between two adjacent gate trenches. A plurality of n+ source regions 911 are formed near a top surface of the P body regions 910 in an active area. A plurality of trenched source-body contacts 915 each filled with a contact metal plug 916 are penetrating through a contact interlayer 909, the n+ source regions 911, the P body regions 910 in the active area and extending into the N type doped column region 940, wherein the trenched source-body contacts 915 have a depth shallower than the gate trenches but deeper than the P body regions 910, connecting the n+ source regions 911 and the P body regions 910 to a source metal 918. The trench MOSFET has double P type doped implant regions along the trenched source-body contacts 915: the first p+ body contact doped implant region 912 is formed along an upper portion of sidewalls of the trenched source-body contacts 915 and below the n+ source regions 911 in the P body regions 910 to reduce body contact resistance; a second Schottky diode doped implant region 913 is surrounding bottom and a lower portion of the sidewalls of each of the trenched source-body contacts 915 underneath the first anti-punch through implant region 912. The second Schottky diode doped implant region 913 has either n− or p− doping type (n− or p−, Schottky diode doped region as illustrated in FIG. 4) depending on the second implant dose. As the lower portion of the trenched source-body contacts 915 and the interfaced second Schottky diode doped implant region 913 together form the embedded Schottky diodes, the embedded Schottky diodes formed within the second implant regions 913 along trench sidewalls and bottom of lower portion of trenched source-body contacts have a depth shallower than the adjacent gate trenches, thus avoiding the high leakage current and enhancing pinch-off effect. According to this embodiment, the contact metal plug 916 can be implemented by a tungsten metal layer padded by a barrier metal layer of Ti/TiN or Co/TiN. A plurality of trenched source-body contacts 915 each filled with a contact metal plug 916 are penetrating through a contact interlayer 909 and extending into the source electrode 907 in trench 904, or extending into the gate electrode 908 in trench 905, wherein the trenched source-body contacts 915 have a depth shallower than the source electrode 907 but deeper than the P body regions 910 and gate electrodes 908, to connect with the source metal 918 and gate metal 920, respectively. The present high performance trench MOSFET has low Qgs (gate-source charge) as top potion of shielded gate between the gate electrodes 908 is narrow enough to be fully oxidized and converted to oxide 931 during gate oxide growth procedure, and low Qrr (reverse recovery charge) due to the built embedded Schottky diode to avoid turn on of a parasitic diode formed between P body 910 and the N doped column 940.

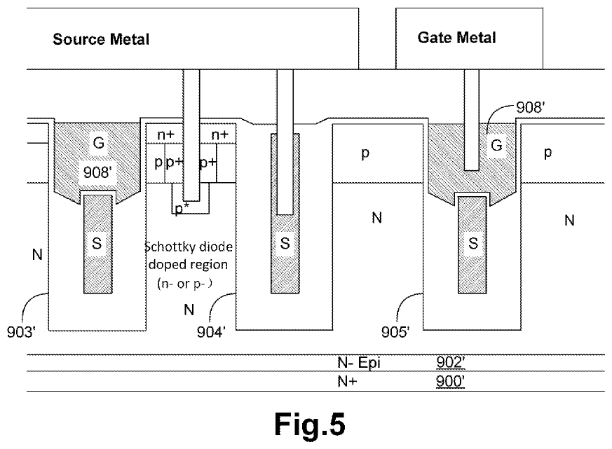

FIG. 5 shows a cross-sectional view of another trench MOSFET with the embedded schottky diode according to the present invention, which is similar to the structure in FIG. 4 except that, the gate electrodes 908 in gate trenches 903 and 904 in FIG. 4 are replaced by single gate electrodes 908′ in gate trenches 903′ and 904′ in FIG. 5.

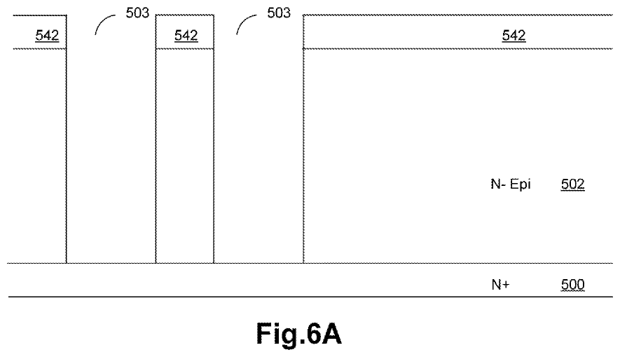

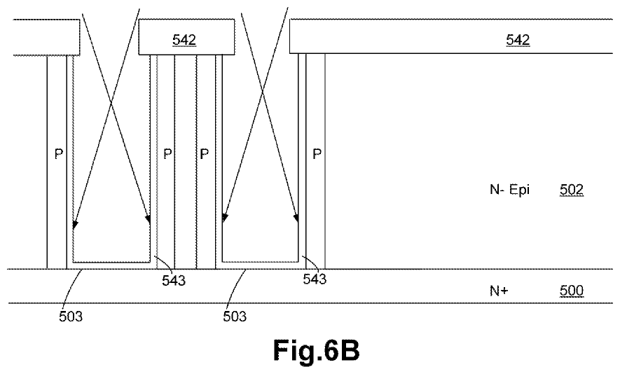

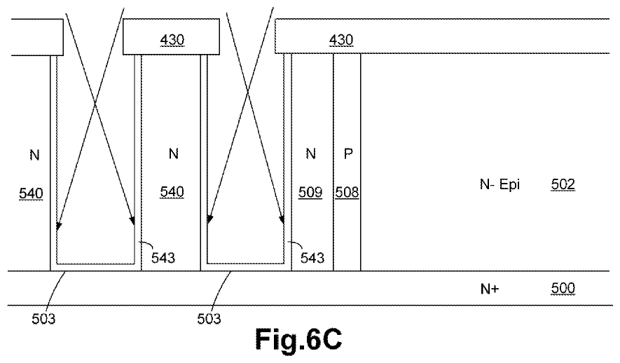

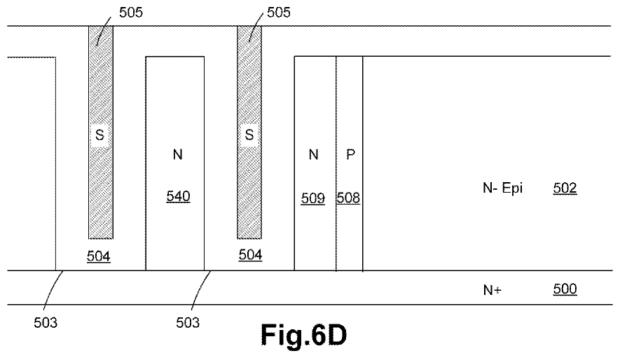

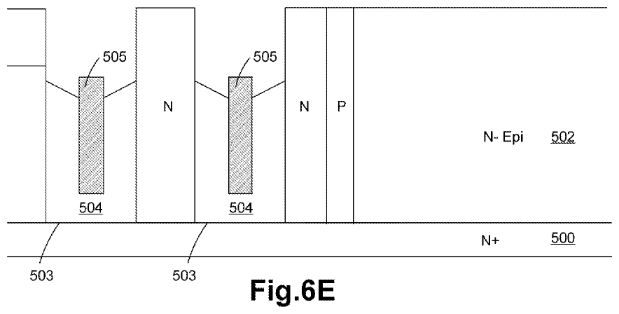

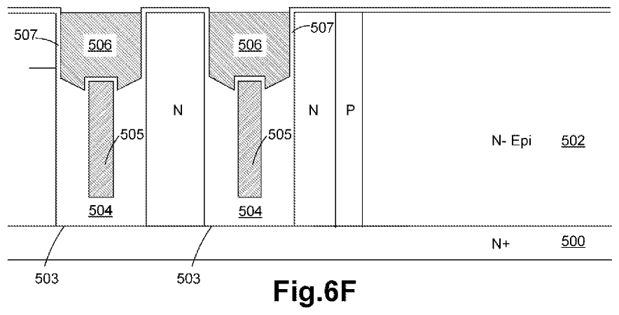

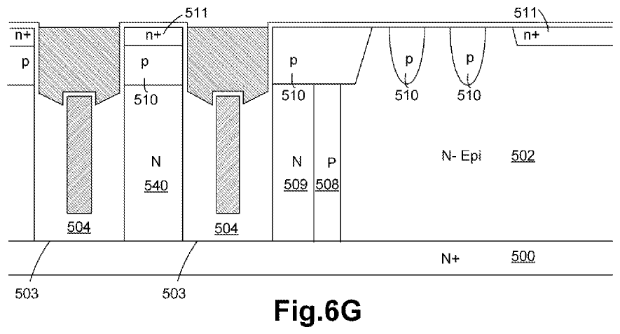

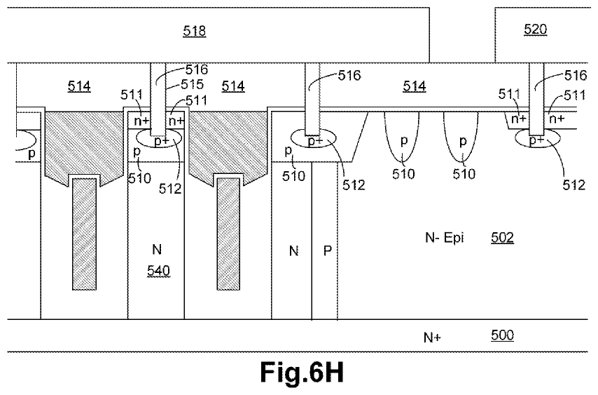

FIGS. 6A-6H are a serial of exemplary steps that are performed to form the inventive shielded gate trench MOSFET in FIG. 2E. In FIG. 6A, an N− epitaxial layer 502 is formed onto an N+ substrate 500, wherein the N+ substrate 500 has a higher doping concentration than the N− epitaxial layer 502. Next, an oxide layer 542 is formed onto a top surface of the N− epitaxial layer 502. Then, after a trench mask (not shown) is applied onto the oxide layer 542, a plurality of trenches 503 are etched penetrating through the oxide layer 542, the N− epitaxial layer 502 and onto the interface between the N− epitaxial layer 502 and N+ substrate 500 by successively dry oxide etch and dry silicon etch.

In FIG. 6B, an isotropic Si etch is performed to eliminate the plasma damage introduced during opening the gate trenches 503. The oxide layer 542 is still substantially remained on the mesas after the isotropic etch to block sequential angle ion implantations into top surfaces of the mesas. After that, a screen oxide 543 is grown along inner surfaces of the gate trenches 503. Then, an angle Ion Implantation of boron dopant is carried out to form a plurality of P type first doped column regions with column shape in the mesas and termination area, and adjacent to sidewalls of the gate trenches 503 within the N− epitaxial layer 502.

In FIG. 6C, another angle Ion Implantation of Arsenic or Phosphorus dopant is carried out, and followed by a diffusion step. As a result of W_{MS}<2 W_{N}, the mesa area only has net N doped column 540 because the NC overrides PC after NC/PC diffusion step, while in termination area, an N type second doped column regions 509 is in parallel surrounded with a P type first doped column regions 508.

In FIG. 6D, the oxide layer 542 and the screen oxide 543 are removed away. A first insulation layer 504 is formed lining the inner surfaces of the trenches 503 by thermal oxide growth or thick oxide deposition. Then, a doped poly-silicon layer is deposited onto the first insulation layer 504 filling the trenches 503 to serve as a source electrode 505.

In FIG. 6E, the source electrode 505 and the first insulation layer 504 are etched back, leaving enough portions in a lower portion of the trenches 503.

In FIG. 6F, a second insulation layer 507 is grown along upper sidewalls of the trenches 503 and a top surface of the source electrode 505, and the second insulation layer 507 has a thinner thickness than the first insulation layer 504. Then, another doped poly-silicon layer is deposited onto the second insulation layer 507 filling an upper portion of the trenches 503 to serve as a gate electrode 506. Next, the gate electrode 506 is etched back by CMP or Plasma Etch.

In FIG. 6G, after applying a body mask (not shown), a step of Ion Implantation with P type dopant is carried out and followed by a diffusion step to form a p body region 510 between every two adjacent trenches 503 and onto the N type first doped column regions 509 and the P type second doped column regions 508, and moreover, multiple p body regions 510 having floating voltage are formed in a termination area. Then, after applying a source mask (not shown), a step of Ion Implantation with N type dopant is carried out to form an n+ source region 511 near a top surface of the P body region 510 and flanking the trenches 503, while another n+ source region 511 is formed in the top surface of the epitaxy layer 502 in the termination area. Furthermore, the n+ source region 511 has a higher doping concentration than the N− epitaxial layer 502.

In FIG. 6H, an oxide layer is deposited onto the top surface of the N− epitaxial layer 502 to serve as a contact interlayer 514. Then, after applying a contact mask (not shown) onto the contact interlayer 514, trenched source-body contacts 515 are formed by successively dry oxide etching and dry silicon etching. The trenched source-body contact 515 are penetrating through the contact interlayer 514, the n+ source region 511 and extending into the p body region 510 in an active area, or through the contact interlayer 514 and extending into the p body region 510, and the epitaxial layer 502 in the termination area. Next, a BF2 Ion Implantation is performed to form a p+ body contact doped region 512 within the p body region 510 or the epitaxy layer 502 in the termination area, and surrounding at least bottom of each the source-body contact 515. The trenched source-body contacts are filled with metal plug 516 comprising a tungsten metal layer padded by a barrier metal layer of Ti/TiN or Co/TiN. A metal layer comprising Al alloys padded with a resistance-reduction layer Ti or Ti/TiN is deposited onto a top surface of the contact interlayer 514 and connected with the metal plug 516. Then, after applying a metal mask, the metal layer is etched to function as a source metal 518 and channel stop metal 520.

Although the present invention has been described in terms of the presently preferred embodiments, it is to be understood that such disclosure is not to be interpreted as limiting. Various alternations and modifications will no doubt become apparent to those skilled in the art reading the above disclosure. Accordingly, it is intended that the appended claims be interpreted as covering all alternations and modifications as fall within the true spirit and scope of the invention.

What is claimed is:

1. A trench MOSFET comprising:
a substrate of a first conductivity type;
an epitaxial layer of said first conductivity type onto said substrate, said epitaxial layer having a lower doping concentration than said substrate;
a plurality of gate trenches formed from a top surface of said epitaxial layer and extending downward into said epitaxial layer in an active area;
a first gate insulation layer formed along trench sidewalls of a lower portion of each of said gate trenches;
a source electrode formed within each of said gate trenches and surrounded by said first gate insulation layer in said lower portion of each of said gate trenches;
a second gate insulation layer formed at least along trench sidewalls of an upper portion of each of said gate trenches and upper sidewalls of said source electrode above said first gate insulation layer, said second gate insulation layer having a thinner thickness than said first gate insulation layer;
a pair of split gate electrodes disposed adjacent to said second gate insulation layer and above said first gate insulation layer in said upper portion of each of said gate trenches;
said gate electrode and said shielded electrode are doped poly-silicon layers
an oxide charge balance region of said first conductivity and having a higher doping concentration than said epitaxial layer, disposed in a mesa between two adjacent said gate trenches;
a body region of a second conductivity type formed in said mesa, above a top surface of said oxide charge region; and
a source region of said first conductivity type formed near a top surface of said body region and adjacent to said split gate electrodes; and
a junction balance region is formed near edge of said active area in a termination area consist of a first doped column region of said first conductivity type having a higher doping concentration than said epitaxial layer, and a second doped column region of said second conductivity type adjacent to said first doped column region.

2. The trench MOSFET of claim 1, wherein said oxide charge balance region has a higher doping concentration near trench sidewalls of said gate trenches than in the center of said mesa.

3. The trench MOSFET of claim 1, wherein each of said split gate electrodes disposed in the middle between said second insulation layer along upper portion of said source electrode and said second insulation layer adjacent trench sidewall of said gate trenches.

4. The trench MOSFET of claim 2, wherein upper portion of said source electrode above said first insulation layer is fully oxidized during said second insulation layer growth.

5. The trench MOSFET of claim 1 further comprising a trenched source-body contact filled with a contact metal plug and penetrating through said source region and extending into said body region; and a body contact doped region of said second conductivity type within said body region and surrounding at least bottom of said trenched source-body contact underneath said source region, wherein said body contact doped region has a higher doping concentration than said body region; and
said contact metal plug is a tungsten metal layer padded by a barrier metal layer of Ti/TiN or Co/TiN.

6. The trench MOSFET of claim 1 wherein said termination further comprising a guard ring connected with said source region and said body region, wherein said guard ring of said second conductivity type have junction depths greater than said body region.

7. The trench MOSFET of claim 1 wherein said termination further comprising a termination area which comprising multiple floating body regions having floating voltage in a termination area wherein said multiple floating body regions having same conductivity type and junction depths as said body regions, formed simultaneously as said body regions.

8. The trench MOSFET of claim 1 further comprising a plurality of trenched source-body contact formed in an active area, each filled with a contact metal plug, penetrating through said source regions and said body regions and extending into said oxide charge balance region in said mesa; and
a body contact doped region of said second conductivity type formed along an upper portion of sidewalls of said trenched source-body contacts below said source regions, wherein said body contact doped region has a higher doping concentration than said body regions; and a Schottky diode doped region surrounding bottoms and a lower portion of sidewalls of said trenched source-body contacts below said body contact doped region, wherein said Schottky diode doped region has either said first or said second conductivity doping type; and
said contact metal plug is a tungsten metal layer padded by a barrier metal layer of Ti/TiN or Co/TiN.

9. The trench MOSFET of claim 1, wherein trench bottoms of said gate trenches are above a common interface between said substrate and said epitaxial layer.

10. The trench MOSFET of claim 1, wherein said gate trenches further touch or extend into said substrate.

11. A trench MOSFET comprising:
a substrate of a first conductivity type;
an epitaxial layer of said first conductivity type onto said substrate, said epitaxial layer having a lower doping concentration than said substrate;
a plurality of gate trenches formed from a top surface of said epitaxial layer and extending downward into said epitaxial layer in an active area;
a first insulation layer along an inner surface of a lower portion of each of said trenches;
a source electrode formed within said lower portion of each of said trenches and surrounded by said first insulation layer;
a second insulation layer formed along inner surfaces of upper portion of each of said trenches and a top surface of said source electrode, said second insulation layer having a thinner thickness than said first insulation layer;
a gate electrode formed within said upper portion of each of said gate trenches and surrounded by said second insulation layer, wherein said gate electrode and said source electrode insulated from each other by a third insulation layer;
said source electrode and said gate electrode comprise a doped poly-silicon of said first conductivity type;
an oxide charge balance region of said first conductivity and having a higher doping concentration than said epitaxial layer, disposed in a mesa between two adjacent said gate trenches;
a body region of a second conductivity type formed in said mesa, above a top surface of said oxide charge region; and
a source region of said first conductivity type formed near a top surface of said body region and adjacent to said split gate electrodes; and
a junction balance region is formed in a termination area consist of a first doped column region of said first conductivity type having a higher doping concentration than said epitaxial layer, and a second doped column region of said second conductivity type adjacent to said first doped column region.

12. The trench MOSFET of claim 11, wherein said oxide charge balance region has a higher doping concentration near trench sidewalls of said gate trenches than in the center of said mesa;

13. The trench MOSFET of claim 11 further comprising a trenched source-body contact filled with a contact metal plug and penetrating through said source region and extending into said body region; and a body contact doped region of said second conductivity type within said body region and surrounding at least bottom of said trenched source-body contact underneath said source region, wherein said body contact doped region has a higher doping concentration than said body region; and
said contact metal plug is a tungsten metal layer padded by a barrier metal layer of Ti/TiN or Co/TiN.

14. The trench MOSFET of claim 11, further comprising a plurality of trenched source-body contact formed in an active area, each filled with a contact metal plug, penetrating through said source regions and said body regions and extending into said oxide charge balance region in said mesa; and
a body contact doped region of said second conductivity type formed along an upper portion of sidewalls of said trenched source-body contacts below said source regions, wherein said body contact doped region has a higher doping concentration than said body regions; and a Schottky diode doped region surrounding bottoms and a lower portion of sidewalls of said trenched source-body contacts below said body contact doped region, wherein said Schottky diode doped region has either said first or said second conductivity doping type; and
said contact metal plug is a tungsten metal layer padded by a barrier metal layer of Ti/TiN or Co/TiN.

15. The trench MOSFET of claim 11, wherein trench bottoms of said gate trenches are above a common interface between said substrate and said epitaxial layer.

16. The trench MOSFET of claim 11, wherein said gate trenches further touch or extend into said substrate.

17. The trench MOSFET of claim 11, wherein said termination further comprising a guard ring connected with said source region and said body region, wherein said guard ring of said second conductivity type have junction depths greater than said body region.

18. The trench MOSFET of claim 11 wherein said termination further comprising a termination area which comprising multiple floating body regions having floating voltage in a termination area wherein said multiple floating body regions having same conductivity type and junction depths as said body regions, formed simultaneously as said body regions.

19. The semiconductor power device of claim 11, wherein said first conductivity type is N type and said second conductivity type is P type.

20. The semiconductor power device of claim 11, wherein said first conductivity type is P type and said second conductivity type is N type.
